(19) United States
(12) Patent Application Publication
(10) Pub. No.: US 2025/0014872 A1
(43) Pub. Date: Jan. 9, 2025

(54) PLASMA PROCESSING METHOD AND PLASMA PROCESSING APPARATUS

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 18/887,050

(22) Filed: Sep. 17, 2024

Related U.S. Application Data
(63) Continuation of application No. PCT/JP2023/008400, filed on Mar. 6, 2023.

(30) Foreign Application Priority Data
Mar. 18, 2022 (JP) 2022-043629

(51) Int. Cl. H01J 37/32

(52) U.S. Cl. CPC H01J 37/32697; H01J 37/32128; H01J 2237/334

(57) ABSTRACT

A plasma processing method includes (a) generating plasma in a chamber of a plasma processing apparatus including a substrate support provided in the chamber and supporting a substrate placed thereon, (b) applying a voltage pulse from a bias power supply to a bias electrode of the substrate support in order to draw ions from the plasma into the substrate, and (c) repeating (b). In (c), a duration length of the voltage pulse is changed to change a potential of the substrate.

### CROSS-REFERENCE TO RELATED APPLICATIONS

This application is a continuation application of International Patent Application No. PCT/JP2023/008400, filed on Mar. 6, 2023, which claims priority from Japanese Patent Application No. 2022-043629, filed on Mar. 18, 2022, with the Japan Patent Office, all of which are incorporated herein in their entireties by reference.

### TECHNICAL FIELD

The present disclosure relates to a plasma processing method and a plasma processing apparatus.

### BACKGROUND

A plasma processing apparatus is used for a plasma processing on substrates. The plasma processing apparatus includes a chamber and a substrate holding electrode provided in the chamber. The substrate holding electrode holds a substrate disposed on the main surface thereof. For example, Japanese Patent Laid-Open Publication No. 2009-187975 discloses the type of plasma processing apparatus.

The plasma processing apparatus disclosed in Japanese Patent Laid-Open Publication No. 2009-187975 further includes a radio-frequency generation device and a DC negative pulse generation device. The radio-frequency generation device applies a radio-frequency voltage to the substrate holding electrode. In the plasma processing apparatus disclosed in Japanese Patent Laid-Open Publication No. 2009-187975, the radio-frequency voltage is alternately switched between ON and OFF. In the plasma processing apparatus disclosed in Japanese Patent Laid-Open Publication No. 2009-187975, a DC negative pulse voltage is applied from the DC negative pulse generation device to the substrate holding electrode according to the ON and OFF timings of the radio-frequency voltage.

### SUMMARY

An embodiment of the present disclosure provides a plasma processing method. The plasma processing method includes (a) generating plasma in a chamber of a plasma processing apparatus. The plasma processing apparatus includes a substrate support provided in the chamber, and the substrate support supports a substrate placed thereon. The plasma processing method further includes (b) applying a voltage pulse from a bias power supply to a bias electrode of the substrate support in order to draw ions from the plasma into the substrate. The plasma processing method further includes (c) repeating (b). In (c), a duration length of the voltage pulse is changed to change a potential of the substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a flowchart of a plasma processing method according to an embodiment.

FIG. 2 is a view illustrating an example of a configuration of a plasma processing system.

FIG. 3 is a view illustrating an example of a configuration of a capacitively coupled plasma processing apparatus.

FIG. 4 is a view illustrating an example of a configuration of a power supply system in the plasma processing apparatus according to an embodiment.

FIGS. 5A and 5B are each an example of a timing chart related to the plasma processing apparatus according to an embodiment.

FIGS. 6A and 6B are each an example of a timing chart related to the plasma processing apparatus according to an embodiment.

FIG. 7 is another example of a timing chart related to the plasma processing apparatus according to an embodiment.

FIG. 8 is a view illustrating another example of the configuration of the power supply system in the plasma processing apparatus according to an embodiment.

FIG. 9 is a partial enlarged cross-sectional view of another example of a substrate support unit.

### DETAILED DESCRIPTION

In the following detailed description, reference is made to the accompanying drawings which form a part hereof. The illustrative embodiments described in the detailed description, drawings, and claims are not meant to be limiting. Other embodiments may be utilized, and other changes may be made without departing from the spirit or scope of the subject matter presented herein.

Hereinafter, various embodiments are described.

An embodiment provides a plasma processing method. The plasma processing method includes (a) generating plasma in a chamber of a plasma processing apparatus. The plasma processing apparatus includes a substrate support provided in the chamber, and the substrate support supports a substrate placed thereon. The plasma processing method further includes (b) applying a voltage pulse from a bias power supply to a bias electrode of the substrate support in order to draw ions from the plasma into the substrate. The plasma processing method further includes (c) repeating (b). In (c), a duration length of the voltage pulse is changed to change a potential of the substrate.

A delay occurs until the potential of the substrate reaches the maximum potential corresponding to a set voltage level of the voltage pulse after the voltage pulse is output by the bias power supply. Thus, the potential of the substrate depends on the duration length of the voltage pulse. Therefore, according to the embodiment above, the potential of the substrate may be changed by changing the duration length of the voltage pulse.

In an embodiment, a period for performing (c) may include a plurality of ON periods and a plurality of OFF periods that alternates with the plurality of ON periods. In each of the plurality of ON periods, the voltage pulse is repeatedly applied from the bias power supply to the bias electrode, and the duration length of the voltage pulse is changed to change the potential of the substrate. In each of the plurality of OFF periods, the application of the voltage pulse from the bias power supply to the bias electrode is stopped.

In an embodiment, during the repetition of the application of the voltage pulse to the bias electrode in each of the plurality of ON periods, the duration length of the voltage pulse may increase. According to this embodiment, the rapid change in plasma impedance is suppressed in each of the plurality of ON periods. Thus, the reflection of the source radio-frequency power used to generate plasma is reduced.

In an embodiment, in each of the plurality of ON periods, the duration length of the voltage pulse may be adjusted to make emission intensity or a deviation of distribution of the emission intensity in the chamber close to a predetermined value.

In an embodiment, a period for performing (c) may include a plurality of ON periods and a plurality of OFF periods that alternates with the plurality of ON periods. In each of the plurality of ON periods, the voltage pulse is repeatedly applied from the bias power supply to the bias electrode. In each of the plurality of OFF periods, the application of the voltage pulse from the bias power supply to the bias electrode is stopped. The duration length of the voltage pulse in at least one ON period of the plurality of ON periods may be set to a different value from the duration length of the voltage pulse in another ON period of the plurality of ON periods. In this embodiment, the potential of the substrate may be changed according to the progress of the plasma processing.

In an embodiment, in (c), an electric bias energy may be periodically applied to the bias electrode. The electric bias energy includes the voltage pulse, and has a waveform cycle. In (c), by changing a duty ratio of the voltage pulse in the waveform cycle, the duration length of the voltage pulse may changed.

In an embodiment, the plasma processing method may further include adjusting a source frequency of the source radio-frequency power to reduce a degree of reflection of the source radio-frequency power supplied to generate the plasma.

In an embodiment, the source frequency may be adjusted in each of a plurality of phase periods within the waveform cycle of the electric bias energy including the voltage pulse.

In an embodiment, (a), (b), and (c) are performed to etch a film of the substrate.

In an embodiment, in (c), a set voltage level of the voltage pulse in the bias power supply may be further changed.

Another embodiment provides a plasma processing apparatus. The plasma processing apparatus includes: a chamber; a substrate support, a plasma generator, and a bias power supply. The substrate support is provided in the chamber. The plasma generator generates plasma in the chamber. The bias power supply repeatedly applies a voltage pulse to a bias electrode of the substrate support, to draw ions from the plasma to a substrate placed on the substrate support. The bias power supply changes a duration length of the voltage pulse, in order to change a potential of the substrate during the repetition of the application of the voltage pulse to the bias electrode.

Hereinafter, the various embodiments are described in detail with reference to the drawings. In the respective drawings, the same or corresponding components are denoted with the same reference numerals.

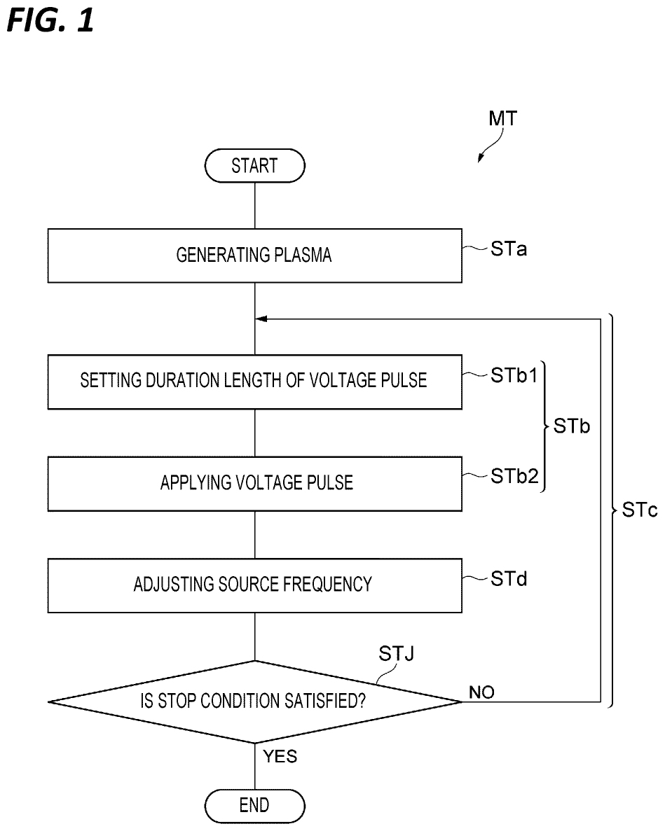

FIG. 1 is a flowchart of a plasma processing method according to an embodiment. The plasma processing method illustrated in FIG. 1 (hereinafter, referred to as a “method MT”) is used in a plasma processing, e.g., etching on substrates. The method MT is performed using a plasma processing apparatus.

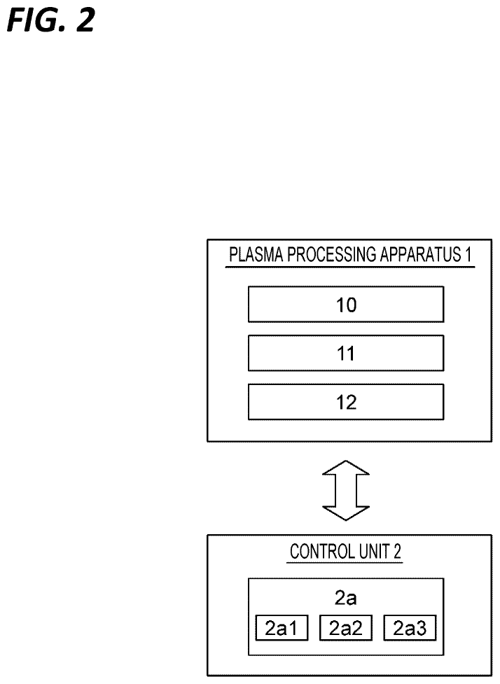

FIG. 2 is a view illustrating an example of a configuration of a plasma processing system. In an embodiment, the plasma processing system includes a plasma processing apparatus 1 and a control unit 2. The plasma processing system is an example of a substrate processing system, and the plasma processing apparatus 1 is an example of a substrate processing apparatus. The plasma processing apparatus 1 includes a plasma processing chamber 10, a substrate support unit 11, and a plasma generation unit 12. The plasma processing chamber 10 has a plasma processing space. The plasma processing chamber 10 has at least one gas supply port for supplying at least one processing gas to the plasma processing space, and at least one gas discharge port for discharging a gas from the plasma processing space. The gas supply port is connected to a gas supply unit 20 to be described herein below, and the gas discharge port is connected to an exhaust system 40 to be described herein below. The substrate support unit 11 is disposed in the plasma processing space, and has a substrate support surface for supporting a substrate thereon.

The plasma generation unit 12 is configured to generate plasma from at least one processing gas supplied into the plasma processing space. The plasma formed in the plasma processing space may be, for example, capacitively coupled plasma (CCP), inductively coupled plasma (ICP), electron-cyclotron-resonance (ECR) plasma, helicon-wave plasma (HWP), or surface wave plasma (SWP).

The control unit 2 processes computer-executable commands for causing the plasma processing apparatus 1 to perform various processes described herein below. The control unit 2 may be configured to control each component of the plasma processing apparatus 1 to perform the various processes described herein. In an embodiment, a portion of the control unit 2 or the entire control unit 2 may be included in the plasma processing apparatus 1. The control unit 2 may include a processing unit 2a1, a storage unit 2a2, and a communication interface 2a3. The control unit 2 is implemented by, for example, a computer 2a. The processing unit 2a1 may be configured to read programs from the storage unit 2a2, and perform various control operations by executing the read programs. The programs may be stored in the storage unit 2a2 in advance, or may be acquired from a medium when necessary. The acquired programs are stored in the storage unit 2a2, and read from the storage unit 2a2 to be executed by the processing unit 2a1. The medium may be any of various storage media readable by the computer 2a, or may be a communication line connected to the communication interface 2a3. The processing unit 2a1 may be a central processing unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as, for example, a local area network (LAN).

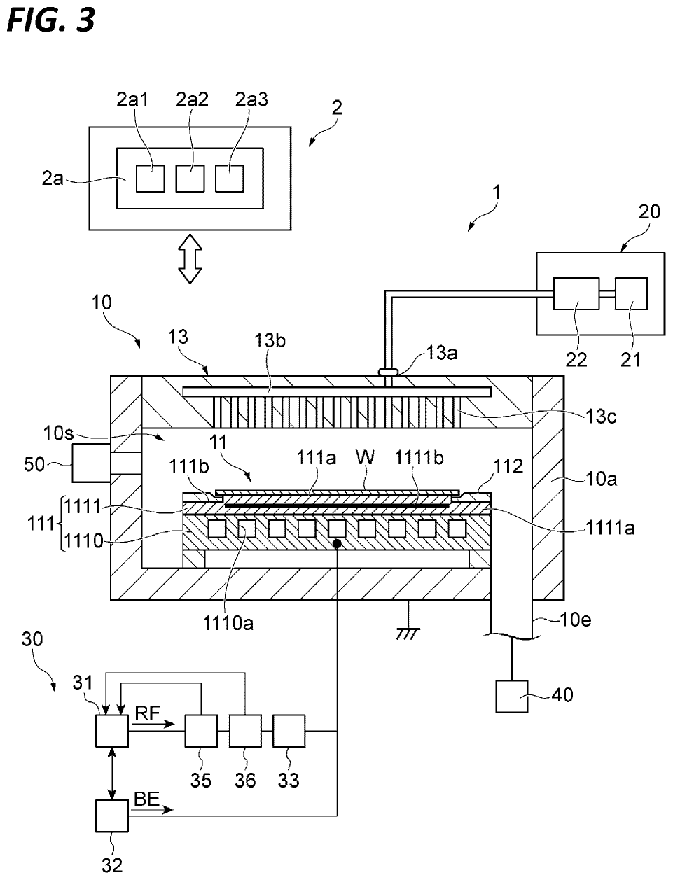

Hereinafter, descriptions will be made on an example of a configuration of a capacitively coupled plasma processing apparatus, which is an example of the plasma processing apparatus 1. FIG. 3 is a view illustrating an example of the configuration of the capacitively coupled plasma processing apparatus.

The capacitively coupled plasma processing apparatus 1 includes the plasma processing chamber 10, the gas supply unit 20, a power supply system 30, and the exhaust system 40. Further, the plasma processing apparatus 1 includes the substrate support unit 11 and a gas introduction unit. The gas introduction unit is configured to introduce at least one processing gas into the plasma processing chamber 10. The gas introduction unit includes a shower head 13. The substrate support unit 11 is disposed in the plasma processing chamber 10. The shower head 13 is disposed above the substrate support unit 11. In an embodiment, the shower head 13 makes up at least a portion of the ceiling of the plasma processing chamber 10. The plasma processing chamber 10 has a plasma processing space 10s defined by the shower head 13, the sidewall 10a of the plasma processing chamber 10, and the substrate support unit 11. The plasma processing chamber 10 is grounded. The substrate support unit 11 is electrically insulated from the casing of the plasma processing chamber 10.

The substrate support unit 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in plan view. The substrate W is placed on the central region 111a of the main body 111, and the ring assembly 112 is disposed on the annular region 111b of the main body 111 to surround the substrate W on the central region 111a of the main body 111. Thus, the central region 111a includes the substrate support surface for supporting the substrate W, and the annular region 111b includes the ring support surface for supporting the ring assembly 112.

In an embodiment, the main body 111 includes a base 1110 and an electrostatic chuck 1111. The base 1110 includes a conductive member. The electrostatic chuck 1111 is disposed on the base 1110. The electrostatic chuck 1111 includes a ceramic member 1111a and an electrostatic electrode 1111b disposed inside the ceramic member 1111a. The ceramic member 1111a has a central region 111a. In an embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 111 and the annular insulating member.

The ring assembly 112 includes one or more annular members. In an embodiment, the one or more annular members include one or more edge rings and at least one covering ring. The edge ring is formed of a conductive or insulating material, and the covering ring is formed of an insulating material.

The substrate support unit 11 may further include a temperature adjustment module configured to adjust at least one of the electrostatic chuck 1111, the ring assembly 112, and the substrate W, to a target temperature. The temperature adjustment module may include a heater, a heat transfer medium, a flow path 1110a, or a combination thereof. A heat transfer fluid such as brine or gas flows in the flow path 1110a. In an embodiment, the flow path 1110a is formed in the base 1110, and one or more heaters are disposed in the ceramic member 1111a of the electrostatic chuck 1111. Further, the substrate support unit 11 may include a heat transfer gas supply unit configured to supply a heat transfer gas to the gap between the back surface of the substrate W and the central region 111a.

The shower head 13 is configured to introduce at least one processing gas from the gas supply unit 20 into the plasma processing space 10s. The shower head 13 includes at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include one or more side gas injectors (SGI) attached to one or more openings formed in the sidewall 10a, in addition to the shower head 13.

The gas supply unit 20 may include at least one gas source 21 and at least one flow controller 22. In an embodiment, the gas supply unit 20 is configured to supply at least one processing gas from each corresponding gas source 21 to the shower head 13 via each corresponding flow controller 22. Each flow controller 22 may include, for example, a mass flow controller or a pressure-controlled flow controller. Further, the gas supply unit 20 may include at least one flow modulation device that modulates or pulses the flow rate of at least one processing gas.

The exhaust system 40 may be connected to a gas discharge port 10e formed at, for example, the bottom of the plasma processing chamber 10. The exhaust system 40 may include a pressure regulation valve and a vacuum pump. The pressure in the plasma processing space 10s is regulated by the pressure regulation valve. The vacuum pump may include a turbo molecular pump, a dry pump, or a combination thereof.

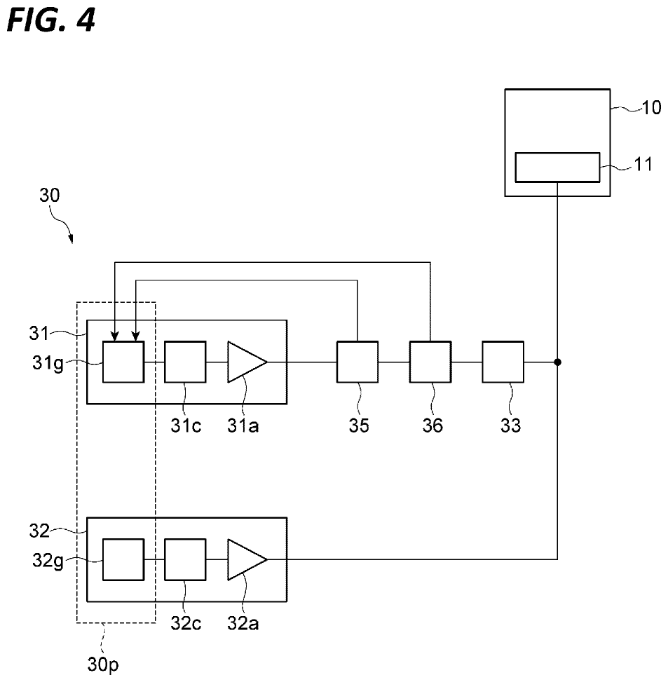

Hereinafter, descriptions are made referring to both FIGS. 3 and 4. FIG. 4 is a view illustrating an example of a configuration of the power supply system in the plasma processing apparatus according to an embodiment. The power supply system 30 includes a radio-frequency power supply 31 and a bias power supply 32. The radio-frequency power supply 31 makes up the plasma generation unit 12 of an embodiment. The radio-frequency power supply 31 is configured to generate a source radio-frequency power RF. The source radio-frequency power RF has a source frequency fRF. That is, the source radio-frequency power RF has a sinusoidal waveform of which frequency is the source frequency fRF. The source frequency fRF may be a frequency in the range of 10 MHz to 150 MHz. The radio-frequency power supply 31 is electrically connected to the radio-frequency electrode via a matcher 33, and is configured to supply the source radio-frequency power RF to the radio-frequency electrode. The radio-frequency electrode may be provided inside the substrate support unit 11. The radio-frequency electrode may be at least one electrode provided inside the conductive member of the base 1110 or the ceramic member 1111a. Alternatively, the radio-frequency electrode may be the upper electrode. When the source radio-frequency power RF is supplied to the radio-frequency electrode, plasma is generated from a gas in the chamber 10.

The matcher 33 has a variable impedance. The variable impedance of the matcher 33 is set to reduce the reflection of the source radio-frequency power RF from a load. The matcher 33 may be controlled by, for example, the control unit 2.

In an embodiment, the radio-frequency power supply 31 may include a signal generator 31g, a D/A converter 31c, and an amplifier 31a. The signal generator 31g generates a radio-frequency signal having the source frequency fRF. The signal generator 31g may be configured with a programmable processor or a programmable logic device such as a field-programmable gate array (FPGA). The signal generator 31g may be configured as a single programmable device together with a signal generator 32g to be described herein below, or may be configured as a separate programmable device from the signal generator 32g.

The output of the signal generator 31g is connected to the input of the D/A converter 31c. The D/A converter 31c converts the radio-frequency signal from signal generator 31g into an analog signal. The output of the D/A converter 31c is connected to the input of the amplifier 31a. The amplifier 31a amplifies the analog signal from the D/A converter 31c to generate the source radio-frequency power RF. The amplification ratio of the amplifier 31a is specified to the radio-frequency power 31 from the control unit 2. The radio-frequency power supply 31 may not include the D/A converter 31c. In this case, the output of the signal generator 31g is connected to the input of the amplifier 31a, which amplifies the radio-frequency signal from the signal generator 31g to generate the source radio-frequency power RF.

The bias power supply 32 is electrically coupled to the substrate support unit 11. The bias power supply 32 is electrically connected to a bias electrode inside the substrate support unit 11, and is configured to supply an electric bias energy BE to the bias electrode. The bias electrode may be at least one electrode provided inside the conductive member of the base 1110 or the ceramic member 1111a. The bias electrode may be common with the radio-frequency electrode. When the electric bias energy BE is supplied to the bias electrode, ions from the plasma are attracted to the substrate W.

In an embodiment, as illustrated in FIG. 4, the bias power supply 32 may include the signal generator 32g, the D/A converter 32c, and the amplifier 32a. The signal generator 32g generates a bias signal with a specified waveform. The signal generator 32g may be configured as a programmable processor or a programmable logic device processor such as an FPGA.

The output of the signal generator 32g is connected to the input of the D/A converter 32c. The D/A converter 32c converts the bias signal from the signal generator 32g into an analog signal. The output of the D/A converter 32c is connected to the input of the amplifier 32a. The amplifier 32a amplifies the analog signal from the D/A converter 32c to generate the electric bias energy BE. The amplification rate of the amplifier 32a is specified to the bias power supply 32 from the control unit 2. The bias power supply 32 may not include the D/A converter 32c. In this case, the output of the signal generator 32g is connected to the input of the amplifier 32a, and the amplifier 32a amplifies the bias signal from the signal generator 32g to generate the electric bias energy BE.

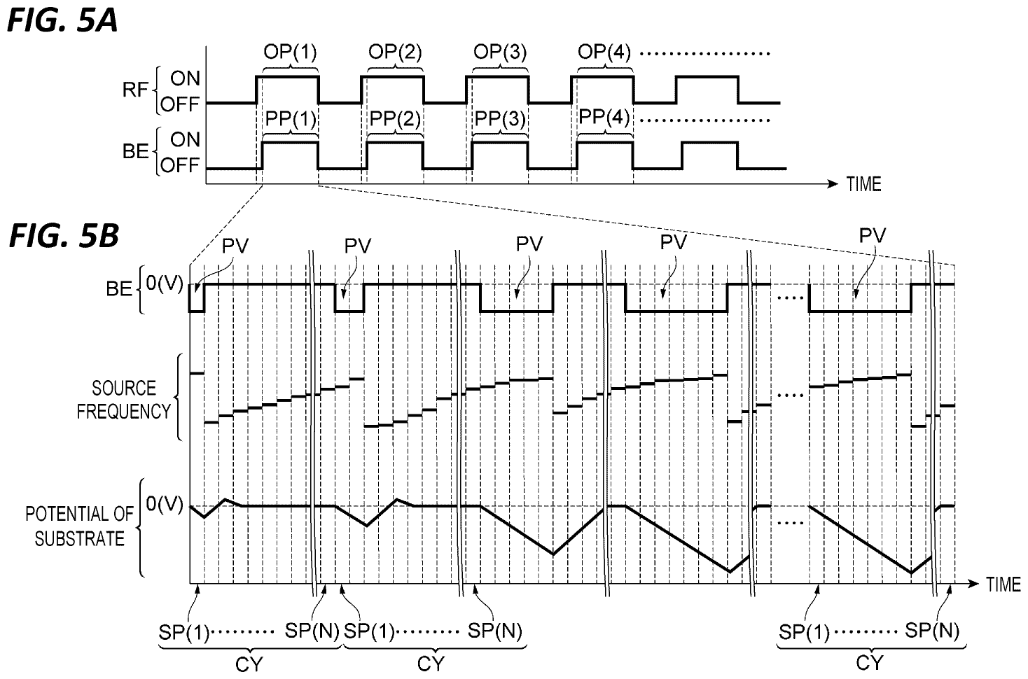

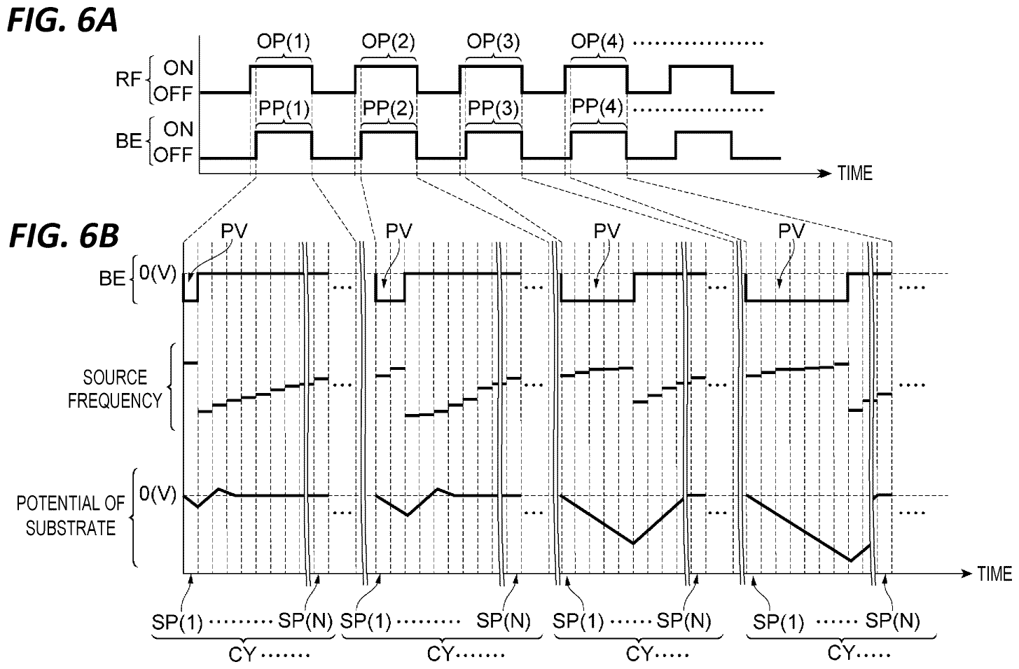

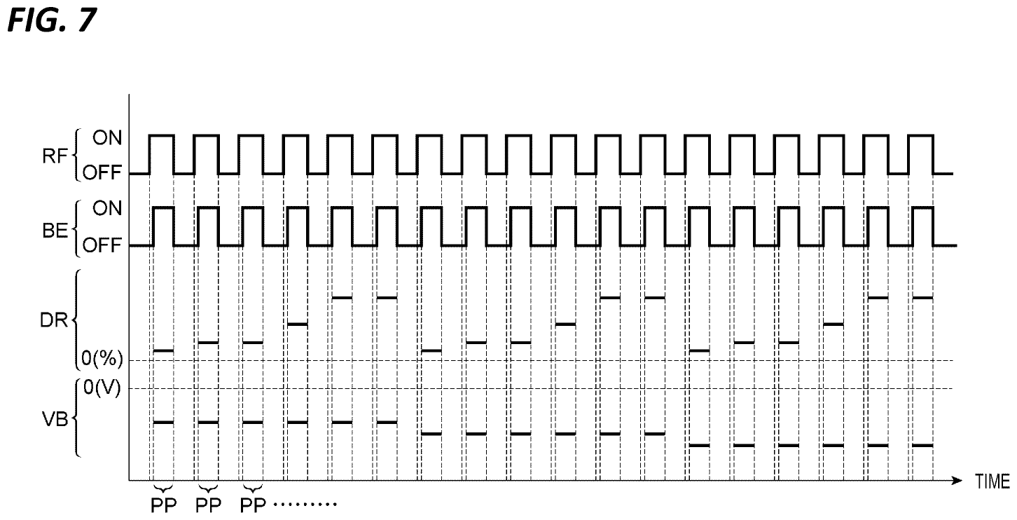

Hereinafter, descriptions are made referring to FIGS. 5A, 5B, 6A, 6B, and 7, in addition to FIGS. 3 and 4. Each of FIGS. 5A, 5B, 6A, 6B, and 7 is an example of a timing chart related to the plasma processing apparatus according to an embodiment. Each of FIGS. 5A, 6A, and 7 illustrates a timing chart of a pulse of the source radio-frequency power RF and a pulse of the electric bias energy BE. In each of FIGS. 5A, 6A, and 7, ON of the source radio-frequency power RF indicates that the pulse of the source radio-frequency power RF is being supplied, and OFF of the source radio-frequency power RF indicates that the supply of the source radio-frequency power RF is stopped. In each of FIGS. 5A, 6A, and 7, ON of the electric bias energy BE indicates that the pulse of the electric bias energy BE is being supplied, and OFF of the electric bias energy BE indicates that the supply of the electric bias energy BE is stopped. Each of FIGS. 5B and 6B illustrates the waveform of the voltage pulse PV of the electric bias energy BE, the source frequency, and the potential of the substrate W. Further, FIG. 7 illustrates the duty ratio DR of the voltage pulse PV in the electric bias energy BE and the set voltage level VB of the voltage pulse PV in the bias power supply 32.

The electric bias energy BE includes a voltage pulse PV. The voltage pulse PV may have a rectangular waveform, a triangular waveform, or any other waveforms. The polarity of the voltage of the voltage pulse PV is set to generate a potential difference between the substrate W and the plasma such that the ions from the plasma may be drawn into the substrate W. The voltage pulse PV may be a negative voltage pulse or a negative DC voltage pulse.

The bias power supply 32 is configured to repeatedly apply the electric bias energy BE to the bias electrode. That is, the bias power supply 32 is configured to repeatedly apply the voltage pulse PV to the bias electrode. Further, the bias power supply 32 is configured to repeatedly apply the pulse of the electric bias energy BE to the bias electrode. That is, the pulse of the electric bias energy BE is applied to the bias electrode in a plurality of ON periods PP. The plurality of ON periods PP appear in sequence. In the descriptions and the drawings herein below, an ON period PP(k) indicates a k-th ON period among the plurality of ON periods PP. In each of the plurality of ON periods PP, the electric bias energy BE is repeatedly applied to the bias electrode. That is, in each of the plurality of ON periods PP, the voltage pulse PV is repeatedly applied to the bias electrode. The repetition of the supply of the pulse of the electric bias energy BE, i.e., the application of the voltage pulse PV to the bias electrode is stopped in the OFF period. The OFF period is a period between two ON periods PP appearing in sequence.

In an embodiment, the bias power supply 32 may be configured to periodically apply the electric bias energy BE having a waveform cycle CY to the bias electrode, in each of the plurality of ON periods PP. That is, in each of the plurality of ON periods PP, the bias power supply 32 may periodically apply the voltage pulse PV to the bias electrode at time intervals of the same length as the time length of the waveform cycle CY. Each of the plurality of waveform cycles CY is defined by a bias frequency. The bias frequency is a frequency of, for example, 50 kHz to 27 MHz. The time length of each of the waveform cycles CY is the reciprocal of the bias frequency.

The bias power supply 32 changes the duration length of the voltage pulse PV to change the potential of the substrate W, during the repetition of the application of the voltage pulse PV to the bias electrode. In an embodiment, the bias power supply 32 changes the duty ratio DR of the voltage pulse PV, thereby changing the duration length of the voltage pulse PV. The duty ratio DR is the ratio (%) of the duration length of the voltage pulse PV in the waveform cycle CY.

A delay occurs until the potential of the substrate W reaches the maximum potential corresponding to the set voltage level of the voltage pulse PV after the voltage pulse PV is output by the bias power supply 32. That is, when the duration length of the voltage pulse PV is sufficiently long, the potential of the substrate W reaches the maximum potential corresponding to the set voltage level of the voltage pulse PV during the period when the voltage pulse PV is applied to the bias electrode. Meanwhile, when the duration length of the voltage pulse PV is short, the application of the voltage pulse PV ends before the potential of the substrate W reaches the maximum potential corresponding to the set voltage level of the voltage pulse PV. Thus, when the duration length of the voltage pulse PV is short, the potential of the substrate W that reaches during the period when the voltage pulse PV is applied to the bias electrode is lower than the maximum potential corresponding to the set voltage level of the voltage pulse PV. In this way, the potential of the substrate W depends on the duration length of the voltage pulse PV. Therefore, according to the plasma processing apparatus 1, the potential of the substrate W may be changed by changing the duration length of the voltage pulse PV.

In an embodiment, as illustrated in FIG. 5B, the bias power supply 32 repeatedly applies the voltage pulse PV to the bias electrode, in each of the plurality of ON periods PP, and may change the duration length of the voltage pulse PV to change the potential of the substrate W.

In an embodiment, as illustrated in FIG. 5B, the bias power supply 32 may increase the duration length of the voltage pulse PV, during the repetition of the application of the voltage pulse PV to the bias electrode in each of the plurality of ON periods PP. As a result, the variation of the impedance of the plasma in the start time period of the plurality of ON periods PP is suppressed, so that the efficiency of the coupling of the source radio-frequency power RF to the plasma is improved.

In an embodiment, the bias power supply 32 may adjust the duration length of the voltage pulse PV to make the emission intensity or the deviation of the distribution of the emission intensity in the chamber 10 close to a predetermined value, during the repetition of the application of the voltage pulse PV to the bias electrode in each of the plurality of ON periods PP. The emission intensity or the deviation of the distribution of the emission intensity in the chamber 10 may be acquired by one or more emission spectrophotometers 50 as illustrated in FIG. 3. For example, the bias power supply 32 decreases the duration length of the voltage pulse PV, when the emission intensity in the chamber 10 is less than the predetermined value, or the deviation of the distribution of the emission intensity in the chamber 10 is larger than the predetermined value.

In an embodiment, as illustrated in FIG. 6B, the bias power supply 32 may set the duration length of the voltage pulse PV in at least one ON period among the plurality of ON periods PP to a different value from the duration length of the voltage pulse PV in another ON period among the plurality of ON periods PP. For example, the bias power supply 32 may change the duration length of the voltage pulse PV in the ON period PP according to the progress of etching on a film of the substrate W. Further, in each of the plurality of ON periods PP, the duration length of the voltage pulse PV may be constant. Alternatively, in each of the plurality of ON periods PP, the duration length of the voltage pulse PV may be changed until reaching a target value. For example, in each of the plurality of ON periods PP, the duration length of the voltage pulse PV may be increased until reaching the target value. Further, in each of the plurality of ON periods PP, the duration length of the voltage pulse PV may be adjusted until reaching the target value, to make the emission intensity or the deviation of the distribution of the emission intensity in the chamber 10 close to the predetermined value.

In an embodiment, the bias power supply 32 may change the set voltage level VB of the voltage pulse PV, in addition to changing the duration length of the voltage pulse PV. For example, as illustrated in FIG. 7, the bias power supply 32 may change the set voltage level VB every two or more ON periods PP appearing in sequence.

In an embodiment, the radio-frequency power supply 31 may alternately repeat ON and OFF of the source radio-frequency power RF. That is, the radio-frequency power supply 31 may repeatedly supply the pulse of the source radio-frequency power RF. The plurality of periods during which the pulse of the source radio-frequency power RF is supplied may coincide with the plurality of ON periods PP, respectively. Alternatively, each of the plurality of periods during which the pulse of the source radio-frequency power RF is supplied may partially overlap with a corresponding ON period PP among the plurality of ON periods PP. Further, the radio-frequency power supply 31 may continuously supply the source radio-frequency power RF. In the following description, the period during which the pulse of the source radio-frequency power RF and the pulse of the electric bias energy BE are supplied simultaneously is referred to as an overlapping period OP. In the plasma processing apparatus 1, a plurality of overlapping periods OP appears in sequence. In the descriptions and the drawings herein below, an overlapping period OP(k) indicates a k-th overlapping period among the plurality of overlapping periods OP.

In an embodiment, the radio-frequency power supply 31 may be configured to adjust the source frequency such that the degree of reflection of the source radio-frequency power RF may be reduced, in at least each of the overlapping periods OP. In an embodiment, the radio-frequency power supply 31 may be configured to adjust the source frequency such that the degree of reflection of the source radio-frequency power RF may be reduced, in each of a plurality of phase periods SP within the waveform cycle CY of the electric bias energy BE. The adjustment of the source frequency is performed by a first feedback and/or a second feedback to be described herein below.

The radio-frequency power supply 31 may modulate the power level of the source radio-frequency power RF. For example, the radio-frequency power supply 31 may modulate the power level of the source radio-frequency power RF in each of the plurality of overlapping periods OP. Alternatively, the radio-frequency power supply 31 may set the power level of the source radio-frequency power RF in at least one overlapping period among the plurality of overlapping periods OP, to a different level from the power level of the source radio-frequency power RF in another overlapping period among the plurality of overlapping periods OP.

### First Feedback

Hereinafter, the first feedback is described. The first feedback is performed to adjust the source frequency in the plurality of phase periods SP of each of a plurality of continuous waveform cycles CY within an overlapping period OP. Each of the plurality of waveform cycles CY includes an “N” number of phase periods SP(1) to SP(N). “N” is an integer equal to or greater than 2. The “N” number of phase periods SP(1) to SP(N) divide each of the plurality of waveform cycles CY into an “N” number of phase periods. In the following description, a waveform cycle CY(m) indicates an m-th waveform cycle among the plurality of continuous waveform cycles CY. A phase period SP(n) indicates an n-th phase period among the phase periods SP(1) to SP(N). Further, a phase period SP(m,n) indicates an n-th phase period in a waveform cycle CY(m).

The adjustment of the source frequency in the first feedback may be performed by the radio-frequency power supply 31 (or the signal generator 31g thereof). The radio- frequency power supply 31 adjusts the source frequency of the source radio-frequency power RF in the phase period SP(m,n) according to the variation of the degree of reflection of the source radio-frequency power RF.

In order to determine the degree of reflection of the source radio-frequency power RF, the plasma processing apparatus 1 may further include a sensor 35 and/or a sensor 36. The sensor 35 is configured to measure the power level Pr of the reflected wave of the source radio-frequency power RF from the load. The sensor 35 includes, for example, a directional coupler. The directional coupler may be provided between the radio-frequency power supply 31 and the matcher 33. Further, the sensor 35 may be further configured to measure the power level Pf of the traveling wave of the source radio-frequency power RF. The power level Pr of the reflected wave measured by the sensor 35 is notified to the radio-frequency power supply 31. Further, the power level Pf of the traveling wave may be notified to the radio-frequency power supply 31 from the sensor 35.

The sensor 36 includes a voltage sensor and a current sensor. The sensor 36 is configured to measure a voltage VRF and a current IRF in a power feed path connecting the radio-frequency power supply 31 and the radio-frequency electrode to each other. The source radio-frequency power RF is supplied to the radio-frequency electrode via the power feed path. The sensor 36 may be provided between the radio-frequency power supply 31 and the matcher 33. The voltage VRF and the current IRF are notified to the radio-frequency power supply 31.

The radio-frequency power supply 31 generates a representative value from measurement values obtained in each of the plurality of phase periods SP. Each measurement value may be the power level Pr of the reflected wave acquired by the sensor 35. The measurement value may be a value of the ratio of the power level Pr of the reflected wave to the output power level of the source radio-frequency power RF (i.e., reflectance). The measurement value may be the phase difference θ0 between the voltage VRF and the current IRF acquired by the sensor 36 in each of the plurality of phase periods SP. The measurement value may be a load-side impedance Z of the radio-frequency power supply 31 in each of the plurality of phase periods SP. The impedance Z is determined from the voltage V_{RF} and the current I_{RF} acquired by the sensor 36. The representative value may be the average or maximum value of the measurement values in each of the plurality of phase periods SP. The radio-frequency power supply 31 uses the representative value in each of the plurality of phase periods SP as a value representing the degree of reflection of the source radio-frequency power RF.

In the first feedback, the radio-frequency power supply 31 identifies the variation of the degree of reflection, by using different source frequencies in corresponding phase periods SP(n) of two or more waveform cycles CY(m), respectively, preceding the waveform cycle CY(m).

By using the different source frequencies in the phase periods SP(n) of the two or more waveform cycles CY, respectively, it is possible to identify the relationship between the change in source frequency (frequency shift) and the variation of the degree of reflection of the source radio-frequency power. Thus, according to the plasma processing apparatus 1, the source frequency used in the phase period SP(m,n) may be adjusted according to the variation of the degree of reflection, such that the degree of reflection is reduced. Further, according to the plasma processing apparatus 1, the degree of reflection may be reduced at a high speed, in each of the plurality of waveform cycles CY in which the electric bias energy BE is applied to the bias electrode of the substrate support unit 11.

In an embodiment, the two or more waveform cycles CY preceding the waveform cycle CY(m) include waveform cycles CY(m−M₁) and CY(m−M₂). Here, M₁ and M₂ are natural numbers satisfying M₁>M₂. In an embodiment, the waveform cycle CY(m−M₁) is a waveform cycle CY(m−2Q), and the waveform cycle CY(m−M₂) is a waveform cycle CY(m−Q). “Q” and “M₂” may be “1,” and “2Q” and “M₁” may be “2.” “Q” may be an integer equal to or greater than 2.

In the first feedback, the radio-frequency power supply 31 gives one frequency shift from the source frequency f(m−M₁,n), to the source frequency f(m−M₂,n). Here, f(m,n) indicates the source frequency of the source radio-frequency power RF used in the phase period SP(m,n). f(m,n) is expressed as f(m,n)=f(m−M₂,n)+Δ(m,n). Δ(m,n) indicates the amount of the frequency shift. The one frequency shift is either one of a frequency decrease and a frequency increase. When the one frequency shift is the frequency decrease, Δ(m,n) has a negative value. When the one frequency shift is the frequency increase, Δ(m,n) has a positive value.

In the first feedback, when the degree of reflection decreases as a result of using the source frequency f(m−M₂,n) obtained by the one frequency shift, the radio-frequency power supply 31 sets the source frequency f(m,n) to a frequency having the one frequency shift with respect to the source frequency f(m−M₂,n). For example, when the power level Pr(m−M₂,n) decreases from the power level Pr(m−M₁,n) due to the one frequency shift, the radio-frequency power supply 31 sets the source frequency f(m,n) to the frequency having the one frequency shift with respect to the source frequency f(m−M₂,n). Pr(m,n) indicates the power level Pr of the reflected wave of the source radio-frequency power RF in the phase period SP(m,n).

In the first feedback, there may be a case where the degree of reflection increases as a result of using the source frequency f(m−M₂,n) obtained by the one frequency shift. For example, the power level Pr(m−M₂,n) of the reflected wave may increase from the power level Pr(m−M₁,n) of the reflected wave due to the one frequency shift. In this case, the radio-frequency power supply 31 may set the source frequency f(m,n) to a frequency having the other frequency shift with respect to the source frequency f(m−M₂,n).

In another embodiment, the source frequency of the source radio-frequency power RF in the phase period SP(m,n) may be obtained as a frequency that minimizes the degree of reflection, from two or more degrees of reflection obtained by using the different source frequencies in the corresponding phase periods SP(n) of the two or more waveform cycles CY(m), respectively, preceding the waveform period CY(m) (e.g., the power levels Pr). The frequency that minimizes the degree of reflection may be obtained by the least square method using the degrees of reflection corresponding to the different frequencies, respectively.

### Second Feedback

Hereinafter, the second feedback is described. In the following description, a waveform cycle CY(m) indicates an m-th waveform cycle among the plurality of waveform cycles CY(1) to CY(m) in each of the plurality of overlapping periods OP. Further, a waveform cycle CY(k,m) indicates an m-th waveform cycle within a k-th overlapping period. The phase period SP(n) indicates an n-th phase period among the plurality of phase periods SP(1) to SP(N) in each of the plurality of waveform cycles CY within each of the plurality of overlapping periods OP. The phase period SP(m,n) indicates an n-th phase period in a waveform period CY(m). The phase period SP(k,m,n) indicates an n-th phase period in a waveform cycle CY(m) within a k-th overlapping period OP (k).

The adjustment of the source frequency of each of the plurality of phase periods SP in each of the plurality of waveform cycles CY within each of the overlapping periods OP(1) to OP(T−1) may be performed by the first feedback described above. Further, “T” is an integer equal to or greater than 3. Alternatively, the source frequency of each of the plurality of phase periods SP in each of the plurality of waveform cycles CY within each of the overlapping periods OP(1) to OP(T−1) may be set to a frequency registered in a table prepared in advance.

For the adjustment of the source frequency of the source radio-frequency power RF in the overlapping period OP(T) and its subsequent overlapping periods, the second feedback may be used. In the second feedback, the radio-frequency power supply 31 adjusts the source frequency f(k,m,n) according to the variation of the degree of reflection of the source radio-frequency power RF described above. In the second feedback, the variation of the degree of reflection is identified by using different source frequencies of the source radio-frequency power RF in the corresponding phase periods SP(n) of the waveform cycles CY(m) within two or more overlapping periods OP preceding the overlapping period OP(k).

In the second feedback, it is possible to identify the relationship between the change in source frequency (frequency shift) and the variation of the degree of reflection of the source radio-frequency power, by using different source frequencies in the same phase period within the same waveform cycle in each of two or more overlapping periods OP. Thus, according to the second feedback, the source frequency used in the phase period SP(k,m,n) may be adjusted according to the variation of the degree of reflection, such that the degree of reflection is reduced. Further, according to the second feedback, the degree of reflection may be reduced at a high speed in each of the plurality of waveform cycles CY within each of the plurality of overlapping periods OP.

In an embodiment, the two or more overlapping periods OP preceding the overlapping period OP(k) include a (k−K₁)-th overlapping period OP(k−K₁) and a (k−K₂)-th overlapping period OP(k−K₂). Here, K₁ and K₂ are natural numbers satisfying K₁>K₂.

In an embodiment, the overlapping period OP(k−K₁) is an overlapping period OP(k−2). The overlapping period OP(k−K₂) is an overlapping period subsequent to the overlapping period OP(k−K₁), and is an overlapping period OP(k−1) in an embodiment. That is, in an embodiment, K₂ and K₁ are 1 and 2, respectively.

The radio-frequency power supply 31 gives one frequency shift form the source frequency in the phase period SP(k−k₁,m,n), to the source frequency f(k−k₂,m,n) in the phase period SP(k−k₂,m,n). Here, f(k,m,n) indicates the source frequency of the source radio-frequency power RF used in the phase period SP(k,m,n). f(k,m,n) is expressed as f(k,m,n)=f(k−K₂,m,n)+Δ(k,m,n). Δ(k,m,n) indicates the amount of the frequency shift. The one frequency shift is either one of a frequency decrease and a frequency increase. When the one frequency shift is the frequency decrease, Δ(k,m,n) has a negative value. When the one frequency shift is the frequency increase, Δ(k,m,n) has a positive value.

In the second feedback, when the degree of reflection decreases as a result of using the source frequency f(k−K₂,m,n) obtained by the one frequency shift, the radio-frequency power supply 31 sets the source frequency f(k,m,n) to a frequency having the one frequency shift with respect to the source frequency f(k−K₂,m,n). For example, when the power level Pr(k−K₂,m,n) decreases from the power level Pr(k−K₁,m,n) due to the one frequency shift, the radio-frequency power supply 31 sets the source frequency f(k,m,n) to the source frequency having the one frequency shift with respect to the source frequency f(k−K₂,m,n). Pr(k,m,n) indicates the power level Pr of the reflected wave of the source radio-frequency power RF in the phase period SP(k,m,n).

In the second feedback, there may be a case where the degree of reflection increases as a result of using the source frequency f(k−K₂,m,n) obtained by the one frequency shift. For example, the power level Pr(k−K₂,m,n) of the reflected wave may increase from the power level Pr(k−K₁,m,n) of the reflected wave due to the one frequency shift. In this case, the radio-frequency power supply 31 may set the source frequency f(k,m,n) to a frequency having the other frequency shift with respect to the source frequency f(k−K₂,m,n).

In another embodiment, the plurality of overlapping periods OP may include first to Kₐ-th overlapping periods OP(1) to OP(Kₐ). Here, Kₐ is a natural number equal to or greater than 2. The radio-frequency power supply 31 may perform an initial process in each of first to Mₐ-th waveform cycles CY(1) to CY(Mₐ) among the plurality of waveform cycles CY included in each of the overlapping periods OP(1) to OP(Kₐ). Here, Mₐ is a natural number. In the initial process, a frequency set group including a plurality of frequency sets for the respective waveform cycles CY(1) to CY(Mₐ) may be used, and the plurality of frequency sets included in the frequency set group may be different from each other. Further, a plurality of frequency set groups for the respective overlapping periods OP(1) to OP(Kₐ) may be used, and the plurality of frequency set groups may be different from each other. For the source frequencies in the plurality of phase periods SP of each of the first to Mₐ-th waveform cycles CY(1) to CY(Mₐ) within each of the overlapping periods OP(1) to OP(Kₐ), the radio-frequency power supply 31 uses the plurality of frequencies included in the corresponding frequency set, respectively. The plurality of frequency sets and the plurality of frequency set groups may be stored in the storage unit of the control unit 2 or the radio-frequency power supply 31.

The radio-frequency power supply 31 may perform the first feedback described above after the waveform cycle CY(Mₐ) among the plurality of waveform cycles CY in each of the overlapping periods OP(1) to OP(Kₐ). That is, the radio-frequency power supply 31 may perform the first feedback described above in waveform cycles CY(Mₐ+1) to CY(M) included in each of the overlapping periods OP(1) to OP(Kₐ).

In an embodiment, the plurality of overlapping periods OP may further include (Kₐ+1)-th to K_{b}-th overlapping periods OP(Kₐ+1) to OP(K_{b}). Here, K_{b} may be a natural number equal to or greater than (Kₐ+1), and may satisfy K_{b}=Kₐ+1.

The radio-frequency power supply 31 may perform the initial process described above in each of first to M_{b1}-th waveform cycles CY(1) to CY(M_{b1}) among the plurality of waveform cycles CY included in each of the overlapping periods OP(Kₐ+1) to OP(K_{b}). Here, M_{b1} is a natural number. M_{b1} and Mₐ may satisfy M_{b1}<Mₐ.

The radio-frequency power supply 31 may perform the second feedback described above in (M_{b1}+1)-th to M_{b2}-th waveform cycles CY(M_{b1}+1) to CY(M_{b2}) among the plurality of waveform cycles CY included in each of the overlapping periods OP(Kₐ+1)-th to OP(K_{b}). Here, M_{b2} is a natural number satisfying M_{b2}>M_{b1}.

The radio-frequency power supply 31 may perform the first feedback described above after a waveform cycle CY(M_{b2}) in each of the overlapping periods OP(Kₐ+1) to OP(K_{b}). That is, the radio-frequency power supply 31 may perform the first feedback described above in waveform cycles CY(M_{b2}+1) to CY(M) included in each of the overlapping periods OP(Kₐ+1) to OP(K_{b}).

Further, the radio-frequency power supply 31 may perform the second feedback described above in first to M_{c}-th waveform cycles CY(1) to CY(M_{c}) included in each of the (K_{b}+1)-th to last overlapping periods OP(K_{b}+1) to OP(K). Here, M_{c} is a natural number. The radio-frequency power supply 31 may perform the first feedback described above after the waveform cycle CY(M_{c}) in each of the overlapping periods OP(K_{b}+1) to OP(K). That is, the radio-frequency power supply 31 may perform the first feedback described above in the waveform cycles CY(M_{c}+1) to CY(M) included in each of the overlapping periods OP(K_{b}+1) to OP(K).

In another embodiment, in the first feedback, the source frequency of the source radio-frequency power RF in the phase period SP(k,m,n) may be obtained as a frequency that minimizes the degree of reflection, from two or more degrees of reflection (e.g., power level Pr) obtained by using different source frequencies of the source radio-frequency power RF in the corresponding phase period SP(n) in each of two or more waveform cycles CY preceding the waveform cycle CY(k,m) within the overlapping period OP(k). The frequency that minimizes the degree of reflection may be obtained by the least square method using the degrees of reflection corresponding to the different frequencies, respectively.

In the second feedback, the source frequency f(k,m,n) may be obtained as a frequency that minimizes the degree of reflection, from two or more degrees of reflection (e.g., power level Pr) obtained by using different source frequencies of the source radio-frequency power RF in the corresponding phase period SP(n) within the waveform cycle CY(m) in two or more overlapping periods OP preceding the overlapping period OP(k). The frequency that minimizes the degree of reflection may be obtained by the least square method using the degrees of reflection corresponding to the different frequencies, respectively.

The method MT is described referring back to FIG. 1. In the following description, the method MT is described assuming an example where the method MT is performed using the plasma processing apparatus 1. In each step of the method MT, each component of the plasma processing apparatus 1 may be controlled by the control unit 2. The method MT may be performed using a separate plasma processing apparatus from the plasma processing apparatus 1.

The method MT is performed in the state where the substrate W is placed on the substrate support unit 11 in order to perform a plasma processing on the substrate W. The plasma processing may be, for example, an etching on a film formed on the substrate W.

The substrate W may have a mask on the film. The mask has a pattern that is transferred to the film of the substrate W through the etching. Alternatively, the substrate W may not have the mask.

As illustrated in FIG. 1, the method MT includes steps STa, STb, and STc. In step STa, plasma is generated in the chamber 10. In step STa, a gas is supplied into the chamber 10 from the gas supply unit 20. In step STa, the pressure in the chamber 10 is set to a specified pressure by the exhaust system 40. In step STa, plasma is generated from the gas in the chamber 10 by the plasma generation unit 12. Specifically, the source radio-frequency power RF is supplied to the radio-frequency electrode from the radio-frequency power supply 31. As described above, the source radio-frequency power RF may be continuously supplied, or the pulse of the source radio-frequency power RF may be intermittently or periodically supplied.

Steo STb is performed to draw ions from the plasma generated in step STa into the substrate W. Step STb includes steps STb1 and STb2. In step STb1, the duration length of the voltage pulse PV is set. In step STb2, the voltage pulse PV having the set duration length is applied to the bias electrode by the bias power supply 32.

After step STb, it is determined in step STJ whether a stop condition is satisfied. The stop condition is satisfied when the time to terminate the plasma processing is reached. When it is determined that the stop condition is not satisfied, step STb is repeated. That is, in step STc, step STb is repeated. In step STc, the duration length of the voltage pulse PV is changed to change the potential of the substrate W. Meanwhile, when it is determined that the stop condition is satisfied in step STJ, the method MT ends.

In an embodiment, the period for performing step STc may include the plurality of ON periods PP and the plurality of OFF periods. The plurality of OFF periods are periods alternating with the plurality of ON periods PP. In each of the plurality of ON periods PP, the voltage pulse PV is repeatedly applied to the bias electrode from the bias power supply 32. In each of the plurality of OFF periods, the application of the voltage pulse PV from the bias power supply 32 to the bias electrode is stopped.

In an embodiment, as described above with reference to FIG. 5B, the duration length of the voltage pulse PV may be changed in order to change the potential of the substrate W, during the repetition of application of the voltage pulse PV to the bias electrode in each of the plurality of ON periods PP. In an embodiment, as described above with reference to FIG. 5B, the duration length of the voltage pulse PV may be increased, during the repetition of application of the voltage pulse PV to the bias electrode in each of the plurality of ON periods PP. In an embodiment, the duration length of the voltage pulse PV may be adjusted in order to make the emission intensity or the deviation of distribution of emission intensity in the chamber 10 close to a predetermined value, during the repetition of the application of the voltage pulse PV to the bias electrode in each of the plurality of ON periods PP.

In an embodiment, as described above with reference to FIG. 6B, the duration length of the voltage pulse PV in at least one ON period among the plurality of ON periods PP may be set to a different value from the duration length of the voltage pulse PV in another ON period among the plurality of ON periods PP. As described above, for example, the duration length of the voltage pulse PV in the ON period PP may be changed according to the progress of etching on the film of the substrate W. In each of the plurality of ON periods PP, the duration length of the voltage pulse PV may be constant. Alternatively, in each of the plurality of ON periods PP, the duration length of the voltage pulse PV may be changed until reaching a target value. For example, in each of the plurality of ON periods PP, the duration length of the voltage pulse PV may be increased until reaching the target value. Further, in each of the plurality of ON periods PP, the duration length of the voltage pulse PV may be adjusted until reaching the target value, such that the emission intensity or the deviation of distribution of emission intensity in the chamber 10 is close to a predetermined value.

In an embodiment, as described above with reference to FIG. 7, the set voltage level VB of the voltage pulse PV may be changed, in addition to changing the duration length of the voltage pulse PV. For example, the set voltage level VB may be changed every two or more ON periods PP appearing in sequence.

In an embodiment, the method MT may further include step STd. Step STd includes adjusting the source frequency to reduce the degree of reflection of the source radio-frequency power RF in at least each of the plurality of overlapping periods OP. In an embodiment, the source frequency may be adjusted to reduce the degree of reflection of the source radio-frequency power RF in each of the plurality of phase periods SP within the waveform cycle CY of the electric bias energy BE. For another specific example of the adjustment of the source frequency, see the descriptions of the first and/or second feedbacks above.

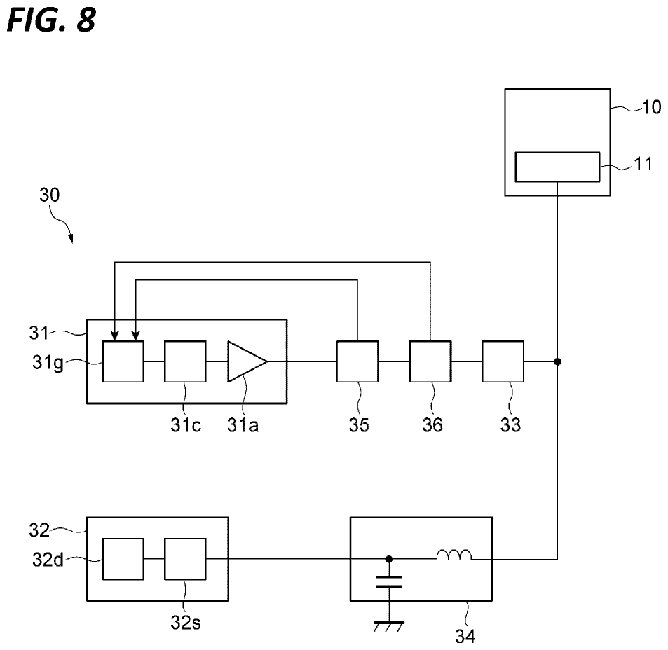

Hereinafter, FIG. 8 is referred to. FIG. 8 is a view illustrating another example of the configuration of the power supply system in the plasma processing apparatus according to an embodiment. As illustrated in FIG. 8, in another embodiment, the bias power supply 32 may include a DC power supply 32d and a switching unit 32s. The DC power supply 32d may be a variable DC power supply. The switching unit 32s generates the voltage pulse PV from a DC voltage output from the DC power supply 32d, by the switch of opening/closing thereof.

As illustrated in FIG. 8, the plasma processing apparatus 1 may further include a damping circuit 34. The damping circuit 34 reduces the variation rate of the voltage level of the voltage pulse PV output from the bias power supply 32. The damping circuit 34 may include an inductor connected between the bias power supply 32 and the bias electrode, and a capacitor connected between one end of the inductor and the ground. The damping circuit 34 may further include a resistor connected in series with the inductor.

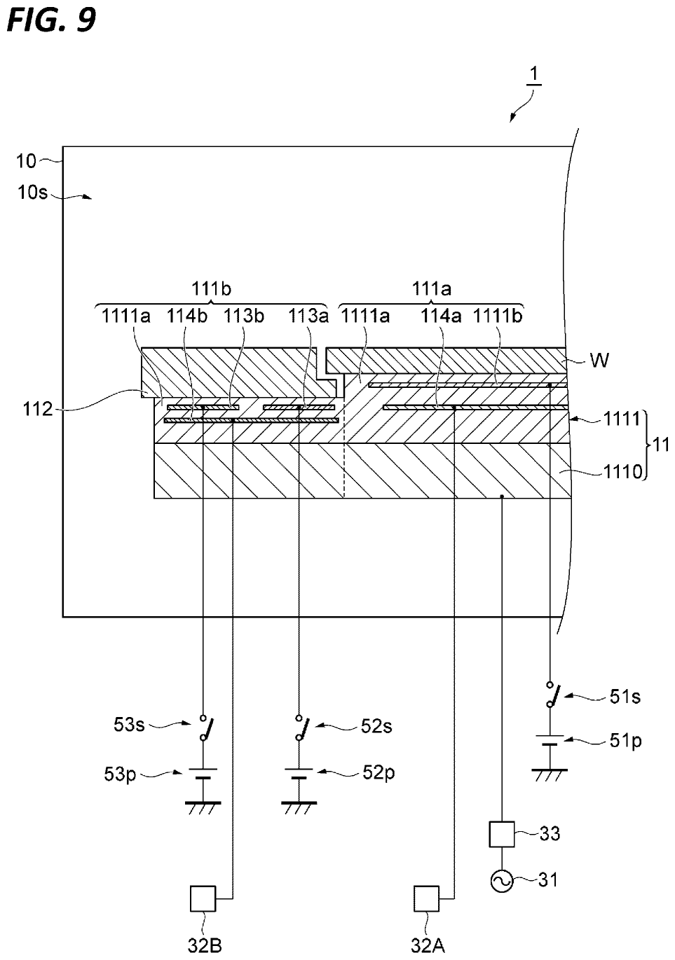

Hereinafter, FIG. 9 is referred to. FIG. 9 is a partial enlarged cross-sectional view of another example of the substrate support unit. As illustrated in FIG. 9, in another embodiment, the substrate support unit 11 may further include electrostatic electrodes 113a and 113b, in addition to the electrostatic electrode 1111b. The electrostatic electrode 1111b is provided inside the ceramic member 1111a in the central region 111a. The electrostatic electrode 1111b may have a substantially circular planar shape. A DC power supply 51p is connected to the electrostatic electrode 1111b via a switch 51s. When a voltage from the DC power supply 51p is applied to the electrostatic electrode 1111b, an electrostatic attraction is generated between the substrate W and the central region 111a. Due to the generated electrostatic attraction, the substrate W is attracted to the central region 111a and held by the central region 111a.

The electrostatic electrodes 113a and 113b are provided inside the ceramic member 111a in the annular region 111b. Each of the electrostatic electrodes 113a and 113b is a single electrode having a substantially ring shape or includes a plurality of electrodes arranged along the circumferential direction. The electrostatic electrode 113a is provided on the inner side of the electrostatic electrode 113b. A DC power supply 52p is connected to the electrostatic electrode 113a via a switch 52s. A DC power supply 53p is connected to the electrostatic electrode 113b via a switch 53s. The DC power supplies 52p and 53p apply voltages to the electrostatic electrodes 113a and 113b in order to generate a potential difference between the electrostatic electrodes 113a and 113b. As a result, an electrostatic attraction is generated between the annular region 111b and the edge ring. Due to the generated electrostatic attraction, the edge ring is attracted to the annular region 111b and held by the annular region 111b. A voltage from a single power supply may be applied to the electrostatic electrodes 113a and 113b as long as a potential difference occurs between the electrostatic electrodes 113a and 113b.

As illustrated in FIG. 9, the substrate support unit 11 may further include bias electrodes 114a and 114b. The bias electrode 114a is provided inside the ceramic member 1111a in the central region 111a. The bias electrode 114a may have a substantially circular planar shape. The bias electrode 114a may be provided between the electrostatic electrode 1111b and the base 1110.

The bias electrode 114b is provided inside the ceramic member 1111a in the annular region 111b. The bias electrode 114b is a single electrode having a substantially ring shape or includes a plurality of electrodes arranged along the circumferential direction. The bias electrode 114b may be provided between each of the electrostatic electrodes 113a and 113b and the base 1110.

In the embodiment illustrated in FIG. 9, two bias power supplies 32A and 32B are employed, instead of the single bias power supply 32. The bias power supplies 32A and 32B may have the same configuration as the bias power supply 32. The bias power supply 32A is electrically connected to the bias electrode 114a, and the bias power supply 32B is electrically connected to the bias electrode 114b. The bias power supplies 32A and 32B repeatedly apply voltage pulses PV synchronized with each other to the bias electrodes 114a and 114b, respectively.

Further, the voltage pulse PV from the single bias power supply may be repeatedly applied to both the bias power supplies 32A and 32B. Further, the electrostatic electrode 1111b may be used as the bias electrode 114a, and the electrostatic electrodes 113a and 113b may be used as the bias electrode 114b.

While various embodiments have been described, the present disclosure is not limited to the embodiments, and various additions, omissions, substitutions, and modifications may be made to the present disclosure. Further, elements in different embodiments may be combined with each other to form other embodiments.

In another embodiment, the plasma processing apparatus may be an inductively coupled plasma processing apparatus, an ECR plasma processing apparatus, a helicon wave excited plasma processing apparatus, or a surface wave plasma processing apparatus. In any of the plasma processing apparatuses, the source radio-frequency power is used to generate plasma, and the source frequency of the source radio-frequency power RF is adjusted as described above with respect to the plasma processing apparatus 1.

Here, the various embodiments included in the present disclosure are described in [E1] to [E11] below.

[E1] A plasma processing method including:
(a) generating plasma in a chamber of a plasma processing apparatus, the plasma processing apparatus including a substrate support provided in the chamber, the substrate support supporting a substrate placed thereon;
(b) applying a voltage pulse from a bias power supply to a bias electrode of the substrate support in order to draw ions from the plasma into the substrate; and
(c) repeating (b),
wherein in (c), a duration length of the voltage pulse is changed to change a potential of the substrate.

[E2] The plasma processing method described in E1, wherein a period for performing (c) includes a plurality of ON periods and a plurality of OFF periods that alternates with the plurality of ON periods,
in each of the plurality of ON periods, the voltage pulse is repeatedly applied from the bias power supply to the bias electrode, and the duration length of the voltage pulse is changed to change the potential of the substrate, and
in each of the plurality of OFF periods, the application of the voltage pulse from the bias power supply to the bias electrode is stopped.

[E3] The plasma processing method described in E2, wherein during the repetition of the application of the voltage pulse to the bias electrode in each of the plurality of ON periods, the duration length of the voltage pulse increases.

[E4] The plasma processing method described in E2 or E3, wherein in each of the plurality of ON periods, the duration length of the voltage pulse is adjusted to make emission intensity or a deviation of distribution of the emission intensity in the chamber close to a predetermined value.

[E5] The plasma processing method described in any one of E1 to E4, wherein a period for performing (c) includes a plurality of ON periods and a plurality of OFF periods that alternates with the plurality of ON periods,
in each of the plurality of ON periods, the voltage pulse is repeatedly applied from the bias power supply to the bias electrode,
in each of the plurality of OFF periods, the application of the voltage pulse from the bias power supply to the bias electrode is stopped, and
the duration length of the voltage pulse in at least one ON period of the plurality of ON periods is set to a different value from the duration length of the voltage pulse in another ON period of the plurality of ON periods.

[E6] The plasma processing method described in any one of E1 to E5, wherein in (c), an electric bias energy including the voltage pulse and having a waveform cycle is periodically applied to the bias electrode, and by changing a duty ratio of the voltage pulse in the waveform cycle, the duration length of the voltage pulse is changed.

[E7] The plasma processing method described in any one of E1 to E6, further including:
adjusting a source frequency of the source radio-frequency power to reduce a degree of reflection of the source radio-frequency power supplied to generate the plasma.

[E8] The plasma processing method described in E7, wherein the source frequency is adjusted in each of a plurality of phase periods within the waveform cycle of the electric bias energy including the voltage pulse.

[E9] The plasma processing method described in any one of E1 to E8, wherein (a), (b), and (c) are performed to etch a film of the substrate.

[E10] The plasma processing method described in any one of E1 to E9, wherein in (c), a set voltage level of the voltage pulse in the bias power supply is further changed.

[E11] A plasma processing apparatus including:
a chamber;
a substrate support provided in the chamber;
a plasma generator that generates plasma in the chamber; and
a bias power supply that repeatedly applies a voltage pulse to a bias electrode of the substrate support, to draw ions from the plasma to a substrate placed on the substrate support,
wherein the bias power supply changes a duration length of the voltage pulse, in order to change a potential of the substrate during the repetition of the application of the voltage pulse to the bias electrode.

According to an embodiment, it is possible to provide a technology of changing a potential of a substrate in a plasma processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing method comprising:
(a) generating plasma in a chamber of a plasma processing apparatus including a substrate support provided in the chamber, the substrate support being configured to support a substrate disposed thereon;
(b) applying a voltage pulse from a bias power supply to a bias electrode of the substrate support in order to draw ions from the plasma into the substrate; and
(c) repeating (b),
wherein in (c), a duration length of the voltage pulse is changed to change a potential of the substrate.

2. The plasma processing method according to claim 1, wherein a period for performing (c) includes a plurality of ON periods and a plurality of OFF periods that alternates with the plurality of ON periods,
in each of the plurality of ON periods, the voltage pulse is repeatedly applied from the bias power supply to the bias electrode, and the duration length of the voltage pulse is changed to change the potential of the substrate, and
in each of the plurality of OFF periods, the application of the voltage pulse from the bias power supply to the bias electrode is stopped.

3. The plasma processing method according to claim 2, wherein during the repetition of the application of the voltage pulse to the bias electrode in each of the plurality of ON periods, the duration length of the voltage pulse increases.

4. The plasma processing method according to claim 2, wherein in each of the plurality of ON periods, the duration length of the voltage pulse is adjusted to make emission intensity or a deviation of distribution of the emission intensity in the chamber close to a predetermined value.

5. The plasma processing method according to claim 1, wherein a period for performing (c) includes a plurality of ON periods and a plurality of OFF periods that alternates with the plurality of ON periods,
in each of the plurality of ON periods, the voltage pulse is repeatedly applied from the bias power supply to the bias electrode,
in each of the plurality of OFF periods, the application of the voltage pulse from the bias power supply to the bias electrode is stopped, and
the duration length of the voltage pulse in at least one ON period of the plurality of ON periods is set to a different value from the duration length of the voltage pulse in another ON period of the plurality of ON periods.

6. The plasma processing method according to claim 1, wherein in (c), an electric bias energy including the voltage pulse and having a waveform cycle is periodically applied to the bias electrode, and by changing a duty ratio of the voltage pulse in the waveform cycle, the duration length of the voltage pulse is changed.

7. The plasma processing method according to claim 1, further comprising:
adjusting a source frequency of the source radio-frequency power to reduce a degree of reflection of the source radio-frequency power supplied to generate the plasma.

8. The plasma processing method according to claim 7, wherein the source frequency is adjusted in each of a plurality of phase periods within the waveform cycle of the electric bias energy including the voltage pulse.

9. The plasma processing method according to claim 1, wherein (a), (b), and (c) are performed to etch a film of the substrate.

10. The plasma processing method according to claim 1, wherein in (c), a set voltage level of the voltage pulse in the bias power supply is further changed.

11. A plasma processing apparatus comprising:
a chamber;
a substrate support provided in the chamber;
a plasma generator configured to generate plasma in the chamber; and
a bias power supply configured to repeatedly apply a voltage pulse to a bias electrode of the substrate support, to draw ions from the plasma to a substrate disposed on the substrate support,
wherein the bias power supply is configured to change a duration length of the voltage pulse, in order to change a potential of the substrate during the repetition of the application of the voltage pulse to the bias electrode.
